(19) United States
(12) Patent Application Publication
(10) Pub. No.: US 2010/0099046 A1
(43) Pub. Date: Apr. 22, 2010

(54) METHOD FOR MANUFACTURING SEMICONDUCTOR DEVICE

(75) Inventors: Hyeong Soo Kim, Yongin-si (KR); Byoung Hoon Lee, Daejeon (KR); Sa Ro Han Park, Yongin-si (KR)

Correspondence Address: AMPACC Law Group, 3500 188th Street S.W., Suite 103, Lynnwood, WA, 98037, US

(73) Assignee: Hynix Semiconductor Inc., Icheon-si (KR)

(21) Appl. No.: 12/489,141

(22) Filed: Jun. 22, 2009

(30) Foreign Application Priority Data
Oct. 21, 2008 (KR) 10-2008-0103325

(51) Int. Cl. G03F 7/20

(52) U.S. Cl. 430/316; 430/319; 430/313

(57) ABSTRACT

A method for manufacturing a semiconductor device comprises forming a protective film over a photoresist pattern to improve the residual ratio of the photoresist pattern. The method comprises forming a photoresist pattern over an underlying layer and forming a protective pattern on an upper portion and sidewalls of the photoresist pattern.

### CROSS-REFERENCE TO RELATED APPLICATION

The priority of Korean patent application No. 10-2008-0103325 filed Oct. 21, 2008, the disclosure of which is hereby incorporated in its entirety by reference, is claimed.

### BACKGROUND OF THE INVENTION

The present invention relates to a method for manufacturing a semiconductor device that comprises forming a protective film over a photoresist pattern to improve the residual ratio of the photoresist pattern.

A semiconductor is a material that could be made to be conductive or non-conductive depending on whether or not it is doped with impurities. The semiconductor is used to produce a semiconductor device such as a transistor by adding impurities to the semiconductor and forming source and drain regions thereon. As the semiconductor device becomes high-integrated, a semiconductor chip size becomes smaller. Improved fabrication processes continually needed to make the chips smaller and smaller.

A semiconductor memory device includes a volatile memory and a non-volatile memory. The volatile memory requires continuous power to retain data. The non-volatile memory does not require power to retain data.

In order to obtain high integration and high yield, much research has been done on improving to photolithography processes to push the limits of the cell structure and the physical properties of a line-forming material and an insulating-film-forming material. The photolithography process is used to form patterns and contact holes on a substrate and form semiconductor devices having multi-layered structures. The limits of the cell structure size cannot be pushed without improving the photolithography process.

The photolithography process utilizes the material called photoresist that experiences physical property changes based on whether or not it is exposed to light. In a typical photolithography process, light is selectively irradiated on a photoresist layer provided over a semiconductor substrate using a mask having a pattern. The pattern defined on the mask is transferred onto the photoresist. This patterned photoresist is transfer the pattern to an underlying material thereto.

As the semiconductor device is made smaller and smaller, a finer and finer pattern is required. However, as the pattern becomes smaller, the residual ratio of the photoresist pattern becomes lower. The residual ratio refers to the stability of the photoresist pattern in the etching process. When an underlying layer exposed by the photoresist pattern is etched, a portion of the photoresist film is also etched. If the thickness of the photoresist pattern is thinner, an etching margin for stably etching a lower layer may be insufficient. One method used to improve the residual ratio of the photoresist pattern is to increase the thickness of the photoresist layer when it is initial formed over a substrate. However, when the photoresist layer is thicker and its patterns are thicker, the resolution and the focus margin are degraded so that it is difficult to form a fine pattern using the photolithography process.

In order to obtain the fine pattern, an organic bottom antireflective coating film is provided below the photoresist film during the photolithography process using a light source having a wavelength less than 248 nm. The bottom antireflective film reduces the reflectivity of the light during the exposure process and increase the light transmissivity. If the light transmissivity is increased by the bottom antireflective coating film in the exposure process, the amount of light reflected to the photoresist film is reduced so that the photoresist film may be patterned to be finer. However, it is difficult to secure an etching selectivity in the photoresist film or the bottom antireflective film that includes a hydrocarbon compound as a main component. As a result, a significant amount of the photoresist pattern is etched away when the lower bottom antireflective coating film is etched with the photoresist pattern as a mask.

For example, when a pattern including the bottom antireflective coating film having a thickness of 24 nm and the photoresist pattern having a thickness of 50 nm is formed, the photoresist pattern experiences a significant loss in order to etch away the exposed bottom antireflective coating film. That is, the thickness of the photoresist pattern becomes significantly thinner. As a result, the residual ratio of the photoresist pattern is degraded so that it may be difficult to etch a layer provided below the bottom antireflective coating film using the remaining photoresist pattern.

### BRIEF SUMMARY OF THE INVENTION

Various embodiments of the invention are directed to providing a method for manufacturing a semiconductor device that comprises forming a protective film over a photoresist pattern to improve the residual ratio of the photoresist pattern.

According to an embodiment of the present invention, a method for manufacturing a semiconductor device comprises: forming a photoresist pattern over an underlying layer; and forming a protective pattern on an upper portion and sidewalls of the photoresist pattern.

Preferably, the method further comprises forming an antireflection coating film between the underlying layer and the photoresist pattern.

Preferably, the forming-a-protective-pattern includes: forming a protective film over the resulting structure including the photoresist pattern; and etching the protective film to expose the underlying layer.

Preferably, the protective film is etched by a plasma process or an etch-back process.

Preferably, the protective film includes one selected from the group consisting of an oxide film, a nitride film and combinations thereof.

Preferably, the protective film is deposited at a temperature ranging from 0 to 250° C.

Preferably, the protective film is formed to be thicker over the photoresist pattern than the underlying layer.

Preferably, the method further comprises etching the underlying layer with the protective pattern as a mask to obtain a fine pattern after forming the protective pattern.

### BRIEF DESCRIPTION OF THE DRAWINGS

FIGS. 1a to 1f are cross-sectional diagrams illustrating a method for manufacturing a semiconductor device according to an embodiment of the present invention.

### DESCRIPTION OF EMBODIMENTS

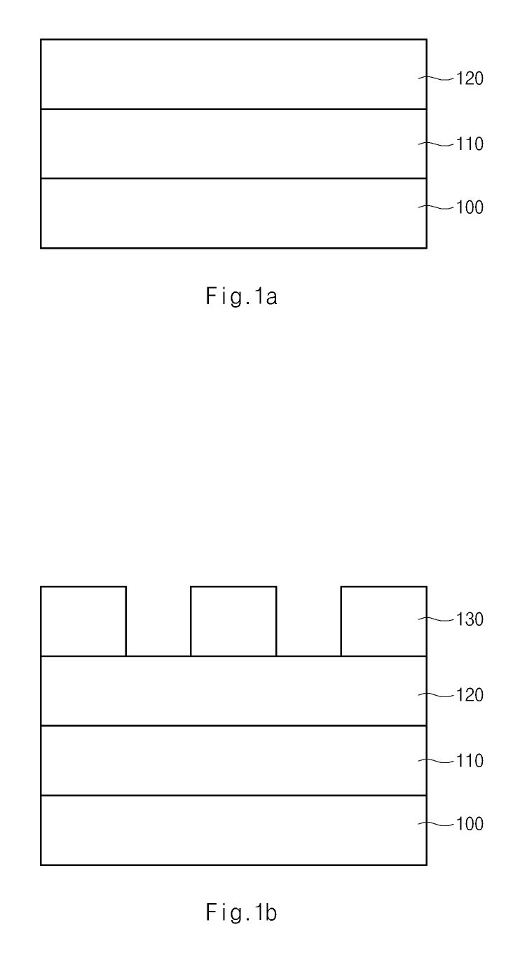

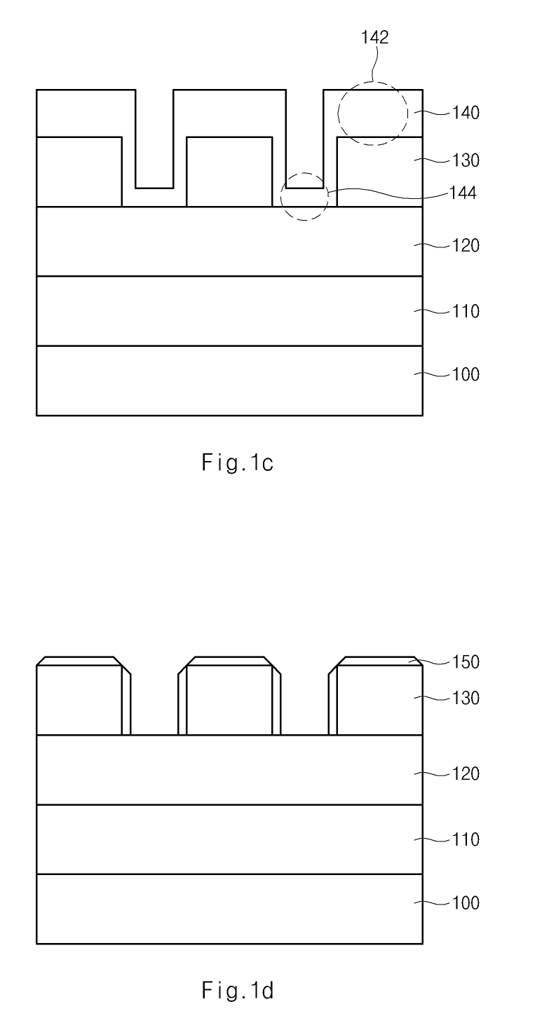

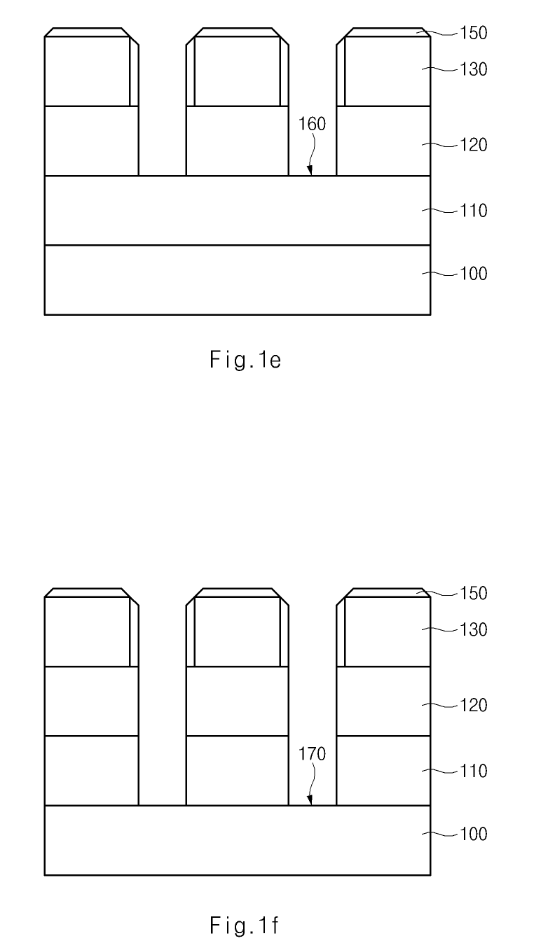

FIGS. 1a to 1f are cross-sectional diagrams illustrating a method for manufacturing a semiconductor device according to an embodiment of the present invention.

FIG. 1a illustrates an underlying layer 110 (or target layer) formed over a semiconductor substrate 100, and an antireflection coating film 120 is deposited over the underlying layer 110.

A photoresist film is coated over the antireflection coating film 120 (FIG. 1b). A photolithography is performed with a fine pattern mask to form a photoresist pattern 130.

A protective film 140 is formed over the resulting structure including the photoresist pattern 130 (FIG. 1c). The protective film 140 includes one selected from the group consisting of an oxide film, a nitride film and a combination thereof. The protective film 140 is formed of a harder material than the photoresist pattern 130 so as to protect the photoresist pattern 130. The protective film 140 is formed at a low temperature, e.g., no more than 250° C., since the photoresist pattern 130 is weak to heat. In one embodiment, the protective film 140 is formed below a glass transition temperature.

In one embodiment, the protective film 140 includes an upper portion 142 formed over the photoresist pattern 130 and a lower portion 144 formed over the antireflection coating film 120. The upper portion 142 is formed to be thicker than the lower portion 144 in the present embodiment.

Referring to FIG. 1d, the protective film 140 is etched, e.g., by a plasma etching or etch-back process to substantially remove the lower portion 144. The protective film 140 is etched at least until the antireflection coating film 120 is exposed. the etching is performed to leave at least a layer of the protective film 140 over the photoresist pattern 130 to protect the photoresist pattern 130. In one embodiment, a protective pattern 150 remains on top and side of the photoresist pattern 130 after the etching of the protective film 140. In another embodiment, the protective pattern 150 only remains on top of the photoresist pattern 130.

Referring to FIG. 1e, the antireflection coating film 120 is etched under an O₂ atmosphere to form a first fine pattern 160. The antireflection coating film 120 formed below the photoresist pattern 130 is etched while the protective pattern 150 protects the photoresist pattern 130. In the present embodiment, the protective pattern 150 is used a mask pattern to etch the antireflection coating film 120.

Referring to FIG. 1f, the underlying layer 110 (or target layer) is etched under an O₂ atmosphere to form a second fine pattern 170. The underlying layer 110 is etched with the protective pattern 150 and the antireflection coating film 120 as etching masks. The protective pattern 150 protects the photoresist pattern 130 while the antireflection coating film 120 and the underlying layer 110 are being etched.

As described above, the method of the present invention comprises forming the protective film over the photoresist pattern, thereby preventing cutting and collapse phenomena of the photoresist pattern due to the thickness loss of the photoresist pattern when the underlying layer is etched. Particularly, the protective film increases the residual ratio of the photoresist pattern so that the fine pattern may be stably formed while the underlying layer is etched, thereby improving yield of the semiconductor device.

The above embodiments of the present invention are illustrative and not limitative. Various alternatives and equivalents are possible. The invention is not limited by the type of deposition, etching polishing, and patterning steps describe herein. Nor is the invention limited to any specific type of semiconductor device. For example, the present invention may be implemented in a dynamic random access memory (DRAM) device or non volatile memory device. Other additions, subtractions, or modifications are obvious in view of the present disclosure and are intended to fall within the scope of the appended claims.

What is claimed is:

1. A method for manufacturing a semiconductor device, the method comprising:
providing a target layer over a substrate;
forming a photoresist pattern over the target layer; and
forming a protective pattern on an upper portion and sidewalls of the photoresist pattern, the protective pattern exposing material provided below the photoresist pattern.

2. The method according to claim 1, further comprising:
forming an antireflection coating film between the target layer and the photoresist pattern, the target being the exposed material.

3. The method according to claim 1, wherein the forming-a-protective-pattern includes:
forming a protective film over the photoresist pattern and the material provided below the photoresist pattern; and
etching the protective film to expose the material provided below the photoresist pattern.

4. The method according to claim 3, wherein the protective film is etched by a plasma process or an etch-back process.

5. The method according to claim 3, wherein the protective film includes one selected from the group consisting of an oxide film, a nitride film and a combination thereof.

6. The method according to claim 3, wherein the protective film is deposited at a temperature of no more than 250° C.

7. The method according to claim 3, wherein the protective film includes an upper portion and a lower portion, the upper portion being thicker than the lower portion.

8. The method according to claim 1, further comprising etching the target layer with the protective pattern.

9. The method according to claim 1, wherein the material provided below the photoresist pattern is an antireflective coating film provided between the target layer and the photoresist pattern.

10. The method according to claim 9, the method further comprising:
etching the antireflective coating film using the protective pattern as an etch mask; and
thereafter, etching the target layer using the protective pattern as an etch mask.

11. The method of claim 10, wherein the antireflective coating film is etched at least until the target layer is exposed.

12. A method for manufacturing a semiconductor device, the method comprising:
providing a target layer over a substrate;
forming a photoresist pattern over the target layer; and
forming a protective pattern at least on an upper portion of the photoresist pattern, the protective pattern exposing material provided below the photoresist pattern.

13. The method according to claim 12, wherein the material provided below the photoresist pattern is an antireflective coating film provided between the target layer and the photoresist pattern.

14. The method according to claim 12, the method further comprising:
etching the antireflective coating film using the protective pattern as an etch mask under an atmosphere including oxygen; and
thereafter, etching the target layer using the protective pattern as an etch mask under an atmosphere including oxygen.

15. The method of claim 14, wherein the antireflective coating film is etched at least until the target layer is exposed.

16. The method of claim 12, wherein the protective pattern is provided on the upper portion and sidewalls of the photoresist pattern.
